(19) United States
(12) Patent Application Publication
(10) Pub. No.: US 2025/0293076 A1
(43) Pub. Date: Sep. 18, 2025

(54) METHOD FOR PRODUCING SEMICONDUCTOR DEVICE

(71) Applicant: Resonac Corporation, Minato-ku, Tokyo (JP)

(72) Inventors: Yuki MIYAMOTO, Minato-ku, Tokyo (JP); Tomohito MOROSAKI, Minato-ku, Tokyo (JP); Katsuhito SUZUKI, Minato-ku, Tokyo (JP); Masayuki WADA, Minato-ku, Tokyo (JP); Keiichi SAKAMOTO, Minato-ku, Tokyo (JP); Masahito WATANABE, Minato-ku, Tokyo (JP); Hidekazu KONDO, Minato-ku, Tokyo (JP); Koichi SAITO, Minato-ku, Tokyo (JP)

(21) Appl. No.: 18/860,111

(22) PCT Filed: Oct. 6, 2023
(86) PCT No.: PCT/JP2023/036605

§ 371 Date: Oct. 25, 2024

(30) Foreign Application Priority Data
Oct. 11, 2022 (JP) 2022-163404

(51) Int. Cl. H01L 21/683; H01L 21/78

(52) U.S. Cl. CPC H01L 21/6836; H01L 21/78; H01L 2221/68381

(57) ABSTRACT

The present disclosure relates to a method for producing a semiconductor device, the method including: a resin film forming step of forming a resin film containing a resin whose molecular weight is reduced by a reaction with water on a semiconductor wafer; a resin film piece-attached semiconductor chip fabrication step of fabricating a resin film piece-attached semiconductor chip individually divided by dicing the semiconductor wafer on which the resin film is formed, with a dicing blade; and a resin film piece removing step of removing the resin film piece from the resin film piece-attached semiconductor chip, by reacting, with water, the resin in the resin film piece of the resin film piece-attached semiconductor chip.

### TECHNICAL FIELD

The present disclosure relates to a method for producing a semiconductor device.

### BACKGROUND ART

A semiconductor device is generally produced through the following steps. First, a semiconductor wafer is attached to a dicing tape, and in this state, the semiconductor wafer is individually divided into semiconductor chips (dicing step). Thereafter, steps, such as a pickup step of picking up the semiconductor chip and a semiconductor chip bonding step of bonding the semiconductor chip picked up and a support member and the like by thermocompression bonding via an adhesive (die-bonding film) or the like, are performed to produce a semiconductor device.

In the dicing step, a fine cut product (debris), created when the semiconductor wafer is cut, can adhere to the circuit formation surface of the semiconductor wafer, leading to an occurrence of a connection failure in a subsequent step. Therefore, it has been studied to provide a resin film (protective film) on the semiconductor wafer, then perform the dicing step, and remove a resin film (protective film) after dicing (e.g., Patent Literatures 1 and 2).

### CITATION LIST

### Patent Literature

Patent Literature 1: Japanese Unexamined Patent Publication No. 2014-172932
Patent Literature 2: Japanese Unexamined Patent Publication No. 2018

### SUMMARY OF INVENTION

### Technical Problem

An object of the present disclosure is to provide a novel method for producing a semiconductor device including a step of forming a resin film on a semiconductor wafer.

### Solution to Problem

The present disclosure provides methods for producing a semiconductor device according to [1] and [2].

[1] A method for producing a semiconductor device, the method including: a resin film forming step of forming a resin film containing a resin whose molecular weight is reduced by a reaction with water on a semiconductor wafer; a resin film piece-attached semiconductor chip fabrication step of fabricating a resin film piece-attached semiconductor chip individually divided by dicing the semiconductor wafer on which the resin film is formed, with a dicing blade; and a resin film piece removing step of removing the resin film piece from the resin film piece-attached semiconductor chip, by reacting, with water, the resin in the resin film piece of the resin film piece-attached semiconductor chip.

[2] The method for producing a semiconductor device according to [1], in which the resin film piece removing step is performed by immersing the resin film piece of the resin film piece-attached semiconductor chip, in water.

### Advantageous Effects of Invention

According to the present disclosure, there is provided a novel method for producing a semiconductor device including a step of forming a resin film on a semiconductor wafer.

### BRIEF DESCRIPTION OF DRAWINGS

FIG. 1 is a schematic cross-sectional view for explaining an embodiment of a method for producing a semiconductor device, and FIGS. 1(a), 1(b), 1(c), and 1(d) are views illustrating respective steps.

FIG. 2 is a schematic cross-sectional view for explaining the embodiment of the method for producing a semiconductor device, and FIGS. 2(a), 2(b), and 2(c) are views illustrating respective steps.

### DESCRIPTION OF EMBODIMENTS

Hereinafter, the present embodiment will be described in detail with reference to the drawings. However, the present disclosure is not limited to the following embodiments. In the following embodiments, the components (including steps and the like) are not essential unless otherwise specified. The same or corresponding portions will be denoted by the same reference signs, and redundant description will be omitted. A positional relationship, such as up, down, left, or right, is based on a positional relationship illustrated in the drawings unless otherwise specified. The sizes of the components in the drawings are conceptual, and the relative relationships between the sizes of the components are not limited to those illustrated in the drawings.

The same applies to numerical values and ranges thereof in the present disclosure, and the present disclosure is not limited thereto. In the present description, a numerical range indicated using “to” indicates a range including numerical values described before and after “to” as a minimum value and a maximum value, respectively. In numerical ranges written in stages in the present description, the upper limit value or the lower limit value written in one numerical range may be replaced with the upper limit value or the lower limit value of another numerical range written in the stages. In a numerical range written in the present description, the upper limit value or the lower limit value of the numerical range may be replaced with a value shown in Examples.

In the present description, the term “layer” includes not only a structure having a shape formed on the entire surface when observed as a plan view, but also a structure having a shape partially formed. In the present description, the term “step” includes not only an independent step but also a step that cannot be clearly distinguished from other steps as long as an intended action of the step is achieved.

In the present description, “(meth)acryloyl” means at least one of acryloyl and methacryloyl. In the present description, “(poly)oxyalkylene group” means at least one of an oxyalkylene group and a polyoxyalkylene group. The polyoxyalkylene group is a group in which two or more alkylene groups are linked by an ether bond. The same applies to other similar expressions such as “(poly)oxyethylene group”.

The components and materials exemplified in the present description may be used singly or in combination of two or more thereof unless otherwise specified.

### [Method for Producing Semiconductor Device]

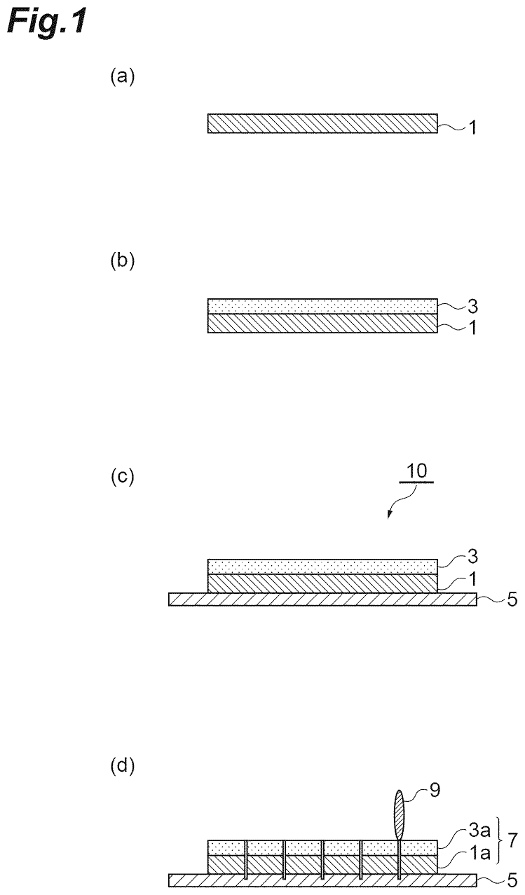

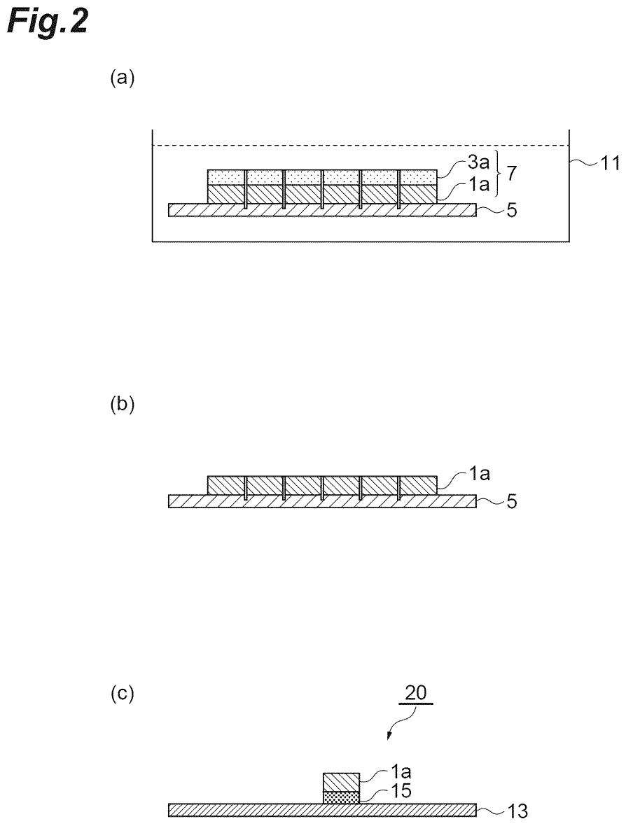

A method for producing a semiconductor device according to an embodiment relates to a method for producing a semiconductor device including a step of forming a resin film (protective film) on a semiconductor wafer. The method for producing a semiconductor device includes a resin film (protective film) forming step, a resin film (protective film) piece-attached semiconductor chip fabrication step, and a resin film (protective film) piece removing step. FIGS. 1 and 2 are schematic cross-sectional views for explaining the embodiment of the method for producing a semiconductor device.

### <Resin Film Forming Step>

In the present step, a resin film 3, containing a resin (hereinafter, it may be referred to as “resin A”) whose molecular weight is reduced by a reaction with water, is formed on a semiconductor wafer 1. The resin A is a resin having a property of improving solubility in water by reducing its molecular weight by a reaction with water. The resin film 3 can act as a protective film for preventing a fine cut product (debris), created when the semiconductor wafer is cut, from adhering to the circuit formation surface of the semiconductor wafer.

In the embodiment, the resin A may be a resin containing an ester bond and a basic functional group. The resin containing an ester bond and a basic functional group is a resin that undergoes a hydrolysis reaction of the ester bond in the presence of the basic functional group by reacting with water, thereby reducing its molecular weight. The resin film 3 can be formed, for example, by solidifying the resin A or a composition containing the resin A, or by reacting and solidifying a precursor of the resin A.

Examples of the basic functional group in the resin A include —NH— and —NH₂.

The resin A can be formed using a resin film forming material containing a compound A, containing two or more first groups and having an ester bond, and a compound B, containing two or more second groups capable of forming bonds with the first groups and capable of forming the resin containing an ester bond and a basic functional group by a reaction with the compound A.

The compound A may contain an ester bond in the first group, and may contain an ester bond as a functional group different from the first group. Examples of the first group in the compound A include a (meth)acryloyloxy group; an isocyanate group; cyclic ether groups (oxirane groups (oxiranyl group, epoxy group), oxetane group (oxetanyl group), tetrahydrofuryl group, tetrahydropyranyl group, and the like); an ethylenically unsaturated group (C═C). The number of the first groups in the compound Al molecule is 2 or more, and may be 3 or more, or 4 or more, and may be 10 or less, 8 or less, 6 or less, or 5 or less.

The compound A may be a compound containing two or more first groups and linking groups linking these first groups. The linking group may include, for example, a (poly)oxyalkylene group. Examples of the (poly)oxyalkylene group include a (poly)oxyethylene group. The linking group may contain at least one skeleton selected from the group consisting of a pentaerythritol skeleton, a trimethylolpropane skeleton, and an isocyanurate skeleton.

The molecular weight or number average molecular weight of the compound A may be 150 or more, 500 or more, or 1,000 or more, and may be 50,000 or less, 10,000 or less, or 2,000 or less. In the present description, the “number average molecular weight” is a polystyrene equivalent value based on a calibration curve using standard polystyrene in gel permeation chromatography method (GPC).

The compound A may be a compound containing two first groups or a compound containing two (meth)acryloyloxy groups. In the case of containing two first groups, the time until the resin A is dissolved in water tends to be longer than in the case of containing two first groups, or the like.

The compound A containing two (meth)acryloyloxy groups may contain a structure represented by the following formula (a1).

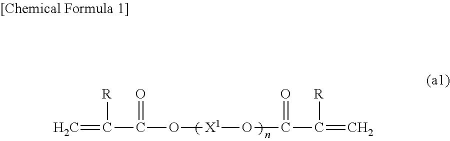

In the formula (a1), R represents a hydrogen atom or a methyl group. X¹ represents an alkylene group. The number of carbon atoms of the alkylene group may be, for example, 2 or more, and may be 10 or less, 6 or less, 4 or less, or 3 or less. The alkylene group may be, for example, an ethylene group (—CH₂—CH₂—).

n represents an integer of 1 or more. n may be, for example, 1 or more, 5 or more, 10 or more, 15 or more, or 20 or more, and may be 50 or less, 45 or less, 40 or less, 35 or less, 30 or less, or 25 or less.

Examples of commercially available products of the compound A containing two (meth)acryloyloxy groups include NK Ester A-1000 (manufactured by Shin-Nakamura Chemical Co., Ltd., chemical name: polyethylene glycol #1000 diacrylate), A-600 (manufactured by Shin-Nakamura Chemical Co., Ltd., chemical name: polyethylene glycol #600 diacrylate), A-400 (manufactured by Shin-Nakamura Chemical Co., Ltd., chemical name: polyethylene glycol #400 diacrylate), A-200 (manufactured by Shin-Nakamura Chemical Co., Ltd., chemical name: polyethylene glycol #200 diacrylate), 2G (manufactured by Shin-Nakamura Chemical Co., Ltd., chemical name: diethylene glycol dimethacrylate), 3G (manufactured by Shin-Nakamura Chemical Co., Ltd., chemical name: triethylene glycol dimethacrylate), 4G (manufactured by Shin-Nakamura Chemical Co., Ltd., chemical name: polyethylene glycol #200 dimethacrylate), 9G (manufactured by Shin-Nakamura Chemical Co., Ltd., chemical name: polyethylene glycol #400 dimethacrylate), 14G (manufactured by Shin-Nakamura Chemical Co., Ltd., chemical name: polyethylene glycol #600 dimethacrylate), 23G (manufactured by Shin-Nakamura Chemical Co., Ltd., chemical name: polyethylene glycol #1000 dimethacrylate), Light Acrylate 3EG-A (manufactured by Kyoeisha Chemical Co., Ltd., chemical name: triethylene glycol dimethacrylate), Light Acrylate 4EG-A (manufactured by Kyoeisha Chemical Co., Ltd., chemical name: polyethylene glycol #200 diacrylate), Light Acrylate 9EG-A (manufactured by Kyoeisha Chemical Co., Ltd., chemical name: polyethylene glycol #400 diacrylate), Light Acrylate 14EG-A (manufactured by Kyoeisha Chemical Co., Ltd., chemical name: polyethylene glycol #600 diacrylate), Light Ester EG (manufactured by Kyoeisha Chemical Co., Ltd., chemical name: ethylene glycol dimethacrylate), Light Ester 2EG (manufactured by Kyoeisha Chemical Co., Ltd., chemical name: diethylene glycol dimethacrylate), Light Ester 3EG (manufactured by Kyoeisha Chemical Co., Ltd., chemical name: triethylene glycol dimethacrylate), Light Ester 4EG (manufactured by Kyoeisha Chemical Co., Ltd., chemical name: polyethylene glycol #200 dimethacrylate), Light Ester 9EG (manufactured by Kyoeisha Chemical Co., Ltd., chemical name: polyethylene glycol #400 dimethacrylate), Light Ester 14EG (manufactured by Kyoeisha Chemical Co., Ltd., chemical name: polyethylene glycol #600 dimethacrylate), Fancryl FA-222A (manufactured by Showa Denko Materials Co., Ltd., chemical name: diethylene glycol diacrylate), Fancryl FA-232A (manufactured by Showa Denko Materials Co., Ltd., chemical name: diethylene glycol diacrylate), Fancryl FA-220A, FA-230A, FA-240A, FA-260A, FA-2100A, and FA-2200A (all manufactured by Showa Denko Materials Co., Ltd., chemical name: polyethylene glycol diacrylate), Fancryl FA-222M (manufactured by Showa Denko Materials Co., Ltd., chemical name: diethylene glycol dimethacrylate), Fancryl FA-232M (manufactured by Showa Denko Materials Co., Ltd., chemical name: diethylene glycol dimethacrylate), and Fancryl FA-220M, FA-230M, FA-240M, FA-260M, FA-2100M, and FA-2200M (all manufactured by Showa Denko Materials Co., Ltd., chemical name: polyethylene glycol dimethacrylate).

The compound A may be a compound containing three or more first groups, or may be a compound containing three or more (meth)acryloyloxy groups.

The compound A containing three or more (meth)acryloyloxy groups may be, for example, a compound represented by the following formula (a2).

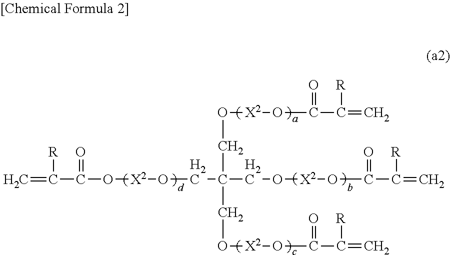

In the formula (a2), R represents a hydrogen atom or a methyl group, and X² represents an alkylene group. a, b, c, and d each independently represent 0 or an integer of 1 or more. A plurality of Rs may be the same or different. The number of carbon atoms of the alkylene group represented by X² may be 2 or more, and may be 10 or less, 6 or less, or 3 or less. The alkylene group represented by X² may be, for example, an ethylene group (—CH₂—CH₂—). When there are a plurality of X²s, they may be the same or different. The sum a+b+c+d of a, b, c, and d may be, for example, 1 or more, 5 or more, 10 or more, 15 or more, 20 or more, 25 or more, or 30 or more, and may be 60 or less, 55 or less, 50 or less, 45 or less, or 40 or less.

Examples of commercially available products of the compound A containing three or more (meth)acryloyloxy groups include NK Ester ATM-35E (manufactured by Shin-Nakamura Chemical Co., Ltd., chemical name: ethoxylated pentaerythritol tetraacrylate), NK Ester A-TMPT-9EO (manufactured by Shin-Nakamura Chemical Co., Ltd., chemical name: ethoxylated trimethylolpropane triacrylate), NK Ester AT-20E (manufactured by Shin-Nakamura Chemical Co., Ltd., chemical name: ethoxylated trimethylolpropane triacrylate),

NK Ester A-GLY-3E (manufactured by Shin-Nakamura Chemical Co., Ltd., chemical name: ethoxylated glycerin triacrylate), NK Ester A-GLY-9E (manufactured by Shin-Nakamura Chemical Co., Ltd., chemical name: ethoxylated glycerin triacrylate),

NK Ester A-GLY-20E (manufactured by Shin-Nakamura Chemical Co., Ltd., chemical name: ethoxylated glycerin triacrylate), and A-DPH-12E (manufactured by Shin-Nakamura Chemical Co., Ltd., chemical name: ethoxylated dipentaerythritol polyacrylate).

The compound A may be a compound exhibiting solubility in water. The solubility of the compound A in 100 g of water at 25° C. may be 1 g or more, 5 g or more, or 10 g or more. The upper limit of the solubility is not particularly limited.

The content of the compound A may be 80 parts by mass or more, 85 parts by mass or more, or 90 parts by mass or more, and may be 99 parts by mass or less, 95 parts by mass or less, or 90 parts by mass or less, based on 100 parts by mass of the total content of the compound A and the compound B.

The second group in the compound B is appropriately selected according to the type of the first group. The combination of the first group and the second group may be, for example, a combination of at least one first group selected from the group consisting of a (meth)acryloyloxy group, an isocyanate group, cyclic ether groups (oxirane groups (oxiranyl group, epoxy group), oxetane group (oxetanyl group), tetrahydrofuryl group, tetrahydropyranyl group, and the like), and an ethylenically unsaturated group (C═C) and at least one second group selected from the group consisting of an amino group, a substituted amino group (e.g., a mono-substituted amino group (—NH—)), and a mercapto group (—SH), and may be a combination of a (meth)acryloyloxy group and an amino group.

The number of the second groups in the compound B1 molecule is 2 or more, and may be 10 or less, 8 or less, 6 or less, 4 or less, or 3 or less, and may be 2. The number of the second groups in the compound B1 molecule may be the same as or different from the number of the first groups in the compound Al molecule, and may be smaller than the number of the first groups in the compound Al molecule.

The compound B may contain a functional group other than the second group. Examples of the functional group other than the second group include an alkylene group and —NH— (imino group).

The compound B may be a compound containing two or more second groups and an alkylene group, a compound containing two or more second groups, an alkylene group, and —NH—, or a compound containing two or more amino groups, an alkylene group, and —NH—.

The compound B may be, for example, a compound represented by the following formula (b).

[Chemical Formula 3]

H₂N—Y—NH₂ (b)

Y represents a divalent group containing an alkylene group. The divalent group containing an alkylene group represented by Y may contain —NH—. The compound B may be, for example, a compound represented by the following formula (b1).

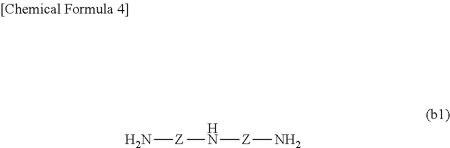

In the formula (b), Z represents an alkylene group. The number of carbon atoms in the alkylene group may be 1 or more, 2 or more, or 3 or more, and may be 10 or less, 8 or less, 6 or less, or 4 or less.

Examples of the compound B include bis(3-aminopropyl)amine, norbornanediamine, ethylenediamine, diethylenetriamine, triethylenetetramine, tetraethylenepentamine, polyetheramine, 4,4′-diaminodiphenylsulfone, 3,3′-diaminodiphenylsulfone, 4,4′-diaminodiphenyl ether, 1,3-bis(3-aminophenoxy)benzene, bisaniline, aminobenzylamine, and polyoxypropylenediamine.

The compound B may be a compound exhibiting solubility in water. The solubility of the compound B in 100 g of water at 25° C. may be 1 g or more, 5 g or more, or 10 g or more. The upper limit of the solubility is not particularly limited.

The ratio (B/A) of the number of moles of the second group (e.g., an amino group) in the compound B to the number of moles of the first group (e.g., a (meth)acryloyl group) in the compound A may be 0.20 or more, 0.40 or more, 0.60 or more, 0.80 or more, or 1.00 or more. The ratio of the number of moles of the compound B to the number of moles of the compound A (the number of moles of the compound B/the number of moles of the compound A) may be, for example, 10.00 or less, 8.00 or less, 6.00 or less, 4.00 or less, 3.00 or less, 2.50 or less, or 2.20 or less.

The content of the compound B may be 1 part by mass or more, 5 parts by mass or more, 8 parts by mass or more, or 10 parts by mass or more, based on 100 parts by mass of the total content of the compound A and the compound B. The content of the compound B may be 20 parts by mass or less, 15 parts by mass or less, 10 parts by mass or less, or 8 parts by mass or less, based on 100 parts by mass of the total content of the compound A and the compound B.

The resin A, which is a reaction product of the compound A and the compound B, can be obtained by mixing or kneading these compounds. The mixing and kneading can be performed by appropriately combining dispersers such as a normal stirrer, a dissolver, a three-roll mill, a ball mill, and a bead mill.

The reaction may be allowed to proceed with heating if necessary. A reaction temperature, at which the compound A and the compound B are reacted, may be, for example, 0° C. or higher, 10° C. or higher, or 20° C. or higher, and may be 100° C. or lower, 85° C. or lower, or 70° C. or lower. The time for holding at the reaction temperature may be, for example, 1.0 minutes or more, and may be 60 minutes or less, 30 minutes or less, 10 minutes or less, 5 minutes or less, or 3 minutes or less.

The resin film 3 may further contain components (other components) other than the resin A. Examples of the other components include additives such as: a plasticizer; a tackiness imparting agent such as tackifier; an antioxidant; a leuco dye; a sensitizer; an adhesion improver such as coupling agent; a polymerization inhibitor; a light stabilizer; an antifoaming agent; a filler; a chain transfer agent; a thixotropy imparting agent; a flame retardant; a release agent; a surfactant; a lubricant; and an antistatic agent. As these additives, known additives can be used. When the resin film 3 contains the other components, the total amount of the contents of the other components may be 0 to 95 mass %, 0.01 to 50 mass %, or 0.1 to 10 mass %, based on the total amount of the resin film 3.

The resin A may be diluted with an organic solvent to be used as a varnish. Examples of the organic solvent include: aromatic hydrocarbons such as toluene, xylene, mesitylene, cumene, and p-cymene; aliphatic hydrocarbons such as hexane and heptane; cyclic alkanes such as methylcyclohexane; cyclic ethers such as tetrahydrofuran and 1,4-dioxane; ketones such as acetone, methyl ethyl ketone, methyl isobutyl ketone, cyclohexanone, and 4-hydroxy-4-methyl-2 pentanone; esters such as methyl acetate, ethyl acetate, butyl acetate, methyl lactate, ethyl lactate, and γ-butyrolactone; carbonate esters such as ethylene carbonate and propylene carbonate; and amides such as N,N-dimethylformamide, N,N-dimethylacetamide, and N-methyl-2-pyrrolidone (NMP). The content of the solid content in the varnish, that is, the content of components other than the organic solvent in the varnish may be 10 to 95 mass %, 15 to 70 mass %, or 20 to 50 mass %, based on the total amount of the varnish.

The resin film forming step may include, for example, a step of preparing the semiconductor wafer 1 (see FIG. 1(a)) and a step of forming the resin film 3 containing the resin A on the semiconductor wafer 1 (see FIG. 1(b)).

Examples of the semiconductor wafer 1 include single crystal silicon, polycrystalline silicon, various ceramics, and compound semiconductors such as gallium arsenide. The semiconductor wafer 1 may have a circuit formation surface.

The thickness of the semiconductor wafer 1 may be, for example, 10 to 1,000 μm, 20 to 900 μm, or 30 to 800 μm.

As a method for forming the resin film on the semiconductor wafer, a method can be used, the method including, for example, applying the resin A or a composition containing the resin A onto the semiconductor wafer by a spin coating method, a slit coating method or the like, and solidifying the applied resin A or composition containing the resin A to form the resin film. The resin film may be disposed, for example, on the circuit formation surface on the semiconductor wafer. The resin may be solidified under a normal temperature condition.

As the method for forming the resin film on the semiconductor wafer, a method can also be used, the method including disposing a curable composition containing the resin A or a precursor of the resin A on the semiconductor wafer, and curing the curable composition disposed on the semiconductor wafer. Examples of the method for disposing a curable composition on the semiconductor wafer include a method for bonding or laminating the curable composition. The method for bonding or laminating the curable composition may be performed under heating or under a normal temperature condition. The precursor of the resin A may be, for example, a mixture of compounds that form the resin A by a reaction proceeding with heating or the like.

As the method for forming the resin film on the semiconductor wafer, a method can also be used, the method including, for example: a step of disposing a curable composition on a substrate to form a curable composition layer; a step of heating the substrate and the curable composition layer to cure the curable composition layer to form a resin film containing a cured product of the curable composition on the substrate, thereby fabricating a first laminate including the substrate and the resin film; a step of bonding or laminating the upper of the semiconductor wafer and the first laminate to each other while heating or at normal temperature so that the semiconductor wafer and the resin film are in contact with each other, thereby fabricating a second laminate including the semiconductor wafer, the resin film, and the substrate in this order; and a step of peeling the substrate from the second laminate, thereby fabricating a third laminate including the semiconductor wafer and the resin film. The curable composition may be cured to a semi-cured state, without being completely cured, before being bonded or laminated, and may be completely cured after being bonded or laminated.

The thickness of the resin film 3 may be, for example, 1 to 1,000 μm, 3 to 500 μm, or 5 to 200 μm.

In this way, the resin film 3 containing the resin A can be formed on the semiconductor wafer 1.

### <Resin Film Piece-Attached Semiconductor Chip Fabrication Step>

In the present step, a resin film piece-attached semiconductor chip 7 individually divided is fabricated by dicing the semiconductor wafer 1 on which the resin film 3 is formed, with a dicing blade 9.

The resin film piece-attached semiconductor chip fabrication step may include, for example, a step of preparing a laminate 10 including a dicing tape 5, the semiconductor wafer 1, and the resin film 3 in this order (see FIG. 1(c)), and a step of, in the laminate 10, dicing at least the semiconductor wafer 1 and the resin film 3 with the dicing blade 9 to obtain the resin film piece-attached semiconductor chip 7 individually divided (see FIG. 1(d)).

Examples of the dicing tape 5 include plastic films such as a polytetrafluoroethylene film, a polyethylene terephthalate film, a polyethylene film, a polypropylene film, a polymethylpentene film, and a polyimide film. If necessary, the dicing tape 5 may be subjected to a surface treatment such as primer application, a UV treatment, a corona discharge treatment, a polishing treatment, or an etching treatment. The dicing tape 5 may be one having tackiness. Such a dicing tape 5 may be one in which tackiness is imparted to the plastic film, or one in which a pressure-sensitive adhesive layer is provided on one surface of the plastic film. The pressure-sensitive adhesive layer may be one including a pressure-sensitive adhesive of an ultraviolet-curable or non-ultraviolet-curable type, and is not particularly limited as long as the pressure-sensitive adhesive layer has sufficient pressure-sensitive adhesive strength so that the semiconductor element does not scatter during dicing, and conventionally known pressure-sensitive adhesive layers can be used.

The thickness of the dicing tape 5 may be, for example, 10 to 1,000 μm, 30 to 500 μm, or 50 to 300 μm.

The laminate 10 can be obtained by attaching the dicing tape 5 to the semiconductor wafer 1 on which the resin film 3 is formed.

Subsequently, in the laminate 10, at least the semiconductor wafer 1 and the resin film 3 (and a part of the dicing tape 5) are diced with the dicing blade 9, thereby dividing each of them into individual pieces. The dicing with the dicing blade 9 can be performed using commercially available equipment. The dicing with the dicing blade 9 is performed on the semiconductor wafer 1 and the resin film 3, for example, in a cutting pattern forming a lattice shape in plan view.

The dicing with the dicing blade 9 may be performed while applying cooling water (cutting water) to a contact portion between the semiconductor wafer 1 or the resin film 3 and the dicing blade 9 from the viewpoint of suppressing a temperature rise at the contact portion. This further suppresses adhesion of a cut product (debris) to the circuit formation surface of the semiconductor wafer.

In this way, each of the semiconductor wafer 1 and the resin film 3 is divided into individual pieces, so that the resin film piece-attached semiconductor chip 7, including a semiconductor chip 1a and a resin film piece 3a, can be obtained.

The shape of the semiconductor chip 1a in plan view may be, for example, a square or a rectangle. The area of the semiconductor chip 1a may be, for example, 1 to 250 mm², 4 to 200 mm², or 9 to 150 mm². The length of one side of the semiconductor chip 1a may be 1 mm or more, 2 mm or more, or 3 mm or more, and may be 20 mm or less, 18 mm or less, or 15 mm or less. The thickness of the semiconductor chip 1a may be similar to the thickness of the semiconductor wafer 1.

### <Resin Film Piece Removing Step>

In the present step, the resin in the resin film piece 3a of the resin film piece-attached semiconductor chip 7 is reacted with water to remove the resin film piece 3a from the resin film piece-attached semiconductor chip 7. Since the resin A contained in the resin film piece 3a is reduced in molecular weight by a reaction with water, solubility in water is improved, so that the resin film piece 3a can be more easily removed from the resin film piece-attached semiconductor chip 7, by water.

In an embodiment, the resin film piece removing step may be a step of removing the resin film piece 3a from the resin film piece-attached semiconductor chip 7, using an aqueous solvent. Since the resin A contained in the resin film piece 3a is reduced in molecular weight by a reaction with water, solubility in water is improved, so that the resin film piece 3a can be sufficiently removed by washing using an aqueous solvent.

Examples of the aqueous solvent include water and a mixed solvent of water and a hydrophilic organic solvent. In the mixed solvent of water and a hydrophilic organic solvent, the ratio of water can be, for example, 80 mass % or more. For example, a pH adjuster may be added to the aqueous solvent.

The aqueous solvent may be water. Examples of the water include tap water, natural water, purified water, distilled water, ion-exchanged water, pure water, and ultrapure water (Milli-Q water or the like). The Milli-Q water means ultrapure water obtained by a Milli-Q water purification system by Merck Millipore (Merck). The water may be purified water, distilled water, ion-exchanged water, pure water, or ultrapure water because impurities are reduced.

Examples of the hydrophilic organic solvent include: alcohols such as methanol, ethanol, 2-propanol, and 1,2-propanediol; and glycol ethers such as ethylene glycol monomethyl ether, propylene glycol monomethyl ether, ethyl cellosolve, propylene glycol monopropyl ether, propylene glycol monoisopropyl ether, butyl cellosolve, ethylene glycol monoisobutyl ether, propylene glycol monobutyl ether, diethylene glycol dimethyl ether, diethylene glycol diethyl ether, and dipropylene glycol monomethyl ether.

Examples of the pH adjuster include an inorganic acid, an inorganic base, an organic acid, and an organic base. Examples of the inorganic acid include nitric acid, sulfuric acid, hydrochloric acid, phosphoric acid, and boric acid. Examples of the inorganic base include sodium hydroxide, potassium hydroxide, and calcium hydroxide. Examples of the organic acid include formic acid, acetic acid, propionic acid, butyric acid, acrylic acid, benzoic acid, and picolinic acid. Examples of the organic base include a primary amine, a secondary amine, a tertiary amine, tetramethylammonium hydroxide, tetraethylammonium hydroxide, and an imidazole-based compound.

The temperature of water, when the resin is reacted with water, may be, for example, 5° C. or higher, 10° C. or higher, 15° C. or higher, 20° C. or higher, 25° C. or higher, 35° C. or higher, 45° C. or higher, or 55° C. or higher, and may be 80° C. or lower or 70° C. or lower. By adjusting the temperature of water or the like when the resin and the water are reacted, it is possible to adjust the time until the resin film piece is dissolved in the water. By raising the temperature of water when the resin is reacted with the water, the resin film piece tends to be dissolved in the water in a shorter time.

The time for reacting the resin with water (the time for maintaining the temperature of the water) may be, for example, 5 minutes or more, 10 minutes or more, or 15 minutes or more, and may be 150 minutes or less or 120 minutes or less. The time for reacting the resin with water (the time for maintaining the temperature of the water) may be 15 to 120 minutes.

In an embodiment, the resin film piece removing step may be a step of immersing the resin film piece 3a of the resin film piece-attached semiconductor chip 7 in an aqueous solvent 11 (see FIG. 2(a)). Since the resin contained in the resin film piece 3a is reduced in molecular weight by a reaction with water, it flows out into the aqueous solvent 11, thereby allowing the resin film piece 3a to be efficiently removed.

In this way, a plurality of the semiconductor chips 1a, in which adhesion of a cut product (debris) is sufficiently suppressed, can be obtained from the semiconductor wafer 1 (see FIG. 2(b)).

The method for producing a semiconductor device according to the present embodiment may further include: an ultraviolet irradiation step of irradiating the pressure-sensitive adhesive layer of the dicing tape 5 with ultraviolet rays; a pickup step of picking up the semiconductor chip 1a; a semiconductor chip bonding step of bonding the semiconductor chip 1a picked up and a support member 13 by thermocompression bonding via an adhesive layer 15 (die-bonding film or the like); a thermal curing step of thermally curing the adhesive layer 15; and the like.

### <Ultraviolet Irradiation Step>

When the pressure-sensitive adhesive layer of the dicing tape 5 contains a pressure-sensitive adhesive of an ultraviolet-curable type, the method for producing a semiconductor device may include an ultraviolet irradiation step. In the present step, the pressure-sensitive adhesive layer is irradiated with ultraviolet rays. In the ultraviolet irradiation, the wavelength of the ultraviolet ray may be 200 to 400 nm. In the ultraviolet irradiation conditions, the illuminance and the irradiation dose may be in a range of 30 to 240 mW/cm² and a range of 50 to 500 mJ/cm², respectively.

### <Pickup Step>

In the present step, the semiconductor chip 1a pushed up with a needle from the side of the dicing tape 5 is sucked by a suction collet and picked up from the dicing tape 5 while separating the individually divided semiconductor chips 1a from each other.

The ultraviolet irradiation step and the pickup step may be performed after the resin film piece removing step, or may be performed before the resin film piece removing step.

### <Semiconductor Chip Bonding Step>

In the present step, the semiconductor chip 1a picked up and the support member 13 are bonded to each other by thermocompression bonding via the adhesive layer 15 (die-bonding film or the like). As the die-bonding film, a die-bonding film used in this field can be used. A plurality of the semiconductor chips 1a may be bonded to the support member 13.

The heating temperature in the thermocompression bonding may be, for example, 80 to 160° C. The load in the thermocompression bonding may be, for example, 5 to 15 N. The heating time in the thermocompression bonding may be, for example, 0.5 to 20 seconds.

### <Thermal Curing Step>

In the present step, the adhesive layer 15 is thermally cured. The heating temperature can be appropriately changed depending on the components of the die-bonding film. The heating temperature may be, for example, 60 to 200° C., 90 to 190° C., or 120 to 180° C. The heating time may be 30 minutes to 5 hours, 1 to 3 hours, or 2 to 3 hours. The temperature or pressure may be changed stepwise.

In this way, a semiconductor device 20 (see FIG. 2(c)) can be produced, the semiconductor device 20 including: the semiconductor chip 1a; the support member 13 on which the semiconductor chip 1a is mounted; and the adhesive layer 15 provided between the semiconductor chip 1a and the support member 13 to bond the semiconductor chip 1a and the support member 13.

### REFERENCE SIGNS LIST

1 Semiconductor wafer
1a Semiconductor chip
3 Resin film
3a Resin film piece
5 Dicing tape
7 Resin film piece-attached semiconductor chip
9 Dicing blade
10 Laminate
11 Aqueous solvent
13 Support member
15 Adhesive layer
20 Semiconductor device

1. A method for producing a semiconductor device, the method comprising:
a resin film forming step of forming a resin film containing a resin whose molecular weight is reduced by a reaction with water on a semiconductor wafer;
a resin film piece-attached semiconductor chip fabrication step of fabricating a resin film piece-attached semiconductor chip individually divided by dicing the semiconductor wafer on which the resin film is formed, with a dicing blade; and
a resin film piece removing step of removing the resin film piece from the resin film piece-attached semiconductor chip, by reacting, with water, the resin in the resin film piece of the resin film piece-attached semiconductor chip.

2. The method for producing a semiconductor device according to claim 1, wherein the resin film piece removing step is performed by immersing the resin film piece of the resin film piece-attached semiconductor chip, in water.
